(19) United States
(12) Patent Application Publication
(10) Pub. No.: US 2003/0181007 A1
(43) Pub. Date: Sep. 25, 2003

(54) Method for reducing random bit failures of flash memories

(76) Inventors: Weng-Hsing Huang, Hsin-Chu City (TW); Kent Kuohua Chang, Taipei City (TW)

Correspondence Address: NAIPO (NORTH AMERICA INTERNATIONAL PATENT OFFICE), P.O. BOX 506, MERRIFIELD, VA, 22116, US

(21) Appl. No.: 10/063,130

(22) Filed: Mar. 25, 2002

(51) Int. Cl. H01L 21/8238; H01L 21/336; H01L 21/4763

(52) U.S. Cl. 438/257; 438/201; 438/211; 438/593

(57) ABSTRACT

A method for reducing random bit failures of flash memory fabrication processes with an ISSG film is disclosed. The random bit failures are caused by HF acid penetration. The ISSG film, which functions as a interface reinforcement layer, is formed on a sacrificial layer and a PL1 layer. With the aid of the ISSG film, the flash memory is free of acid-corroded seams.

### BACKGROUND OF INVENTION

1. Field of the Invention

The present invention relates to a method for reducing random bit failures of flash memory fabrication processes, and more particularly, it relates to a high gate coupling ratio (GCR) and high reliability flash memory fabrication method utilizing an in-situ steam generation (ISSG) film, which functions as an interface reinforcement layer, to effectively protect flash memory cells from HF acid corrosion during the fabrication processes.

2. Background of the Invention

For the past few years, there has been an increasing demand for portable electronic products, such as electronic film for digital cameras, mobile phones, video game apparatuses, personal digital assistants (PDA), MP3 players, etc. Such demand pushes the development of flash memory fabrication technology. Because of its highly reduced weight and physical dimension compared to magnetic memories, such as hard disk or floppy disk memories, flash memory has a tremendous potential in the consumer electronics market.

Flash memory is a high-density, nonvolatile semiconductor memory that offer fast access times. Flash memory can retain data in memory under an electrical power off state, and read and write data through controlling a threshold voltage of a control gate. Flash memory is typically designed as a stacked-gate structure. In a stacked-gate flash memory operation, the stacked-gate electrode comprises a control gate and one or more floating gates separated by a dielectric layer. When the control gate is charged, hot electrons travel across the dielectric layer and cause the floating gate to be charged. After the power is turned off, the oxide layer surrounding the floating gate prevents the charge from dissipating. Data storing in the memory is renewed/erased by applying extra energy to the stacked-gate flash memory cell. The control-gate-to-floating-gate coupling ratio, or the gate coupling ratio (GCR), which is related to the area overlap between control gate and the floating gate, affects the read/write speed of the flash memory.

Please refer to FIG. 1 to FIG. 4. FIG. 1 to FIG. 4 are cross-sectional diagrams of forming a dual-bit stacked-gate flash memory cell according to the prior art. As shown in FIG. 1, a semiconductor wafer 10 comprises a silicon substrate 12, an active area 11 isolated by a field oxide layer 14 positioned on the silicon substrate 12, and two gate structures 21 positioned within an active area 11 on the silicon substrate 12. Each gate structure 21 comprises a gate oxide layer 16 formed on the silicon substrate 12, a polysilicon layer (hereinafter referred to as a PL1 layer) 18 positioned on the gate oxide layer 16, and a silicon nitride layer 20 positioned atop the PL1 layer 18.

According to the prior art, as shown in FIG. 2, an ion implantation process is performed to implant ions into the surface of the silicon substrate 12 that is not covered by the gate structure 21, i.e. into a bit line region. A thermal oxidation process is then performed to activate the doping ions to form a diffusion layer 22 that serves as a buried drain or source (BD/BS), or a bit line. A thermal oxide layer or BD/BS oxide layer 24 growth step over the diffusion layer 22 then follows. As shown in FIG. 3, the silicon nitride layer 20 is then removed and a polysilicon layer 26 is formed over each PL1 layer 18. The PL1 layer 18 and the polysilicon layer 26 form a floating gate 28.

As shown in FIG. 4, a dielectric layer 30 is formed on the surface of the floating gate 28, and a polysilicon layer 32 is then formed that serves as a control gate of the stacked-gate flash memory cell. Typically, the dielectric layer 30 is an ONO structure that comprises a bottom oxide layer, a nitride layer positioned on the bottom oxide layer and a top oxide layer positioned on the nitride layer.

The drawbacks of the prior art method of making a flash memory cell include: 1) Since the BD/BS oxide layer 24 is formed by a thermal oxidation method, the thickness of the BD/BS oxide layer 24 is not uniform from a wafer-to-wafer aspect or a die-to-die aspect, thus causing a reliability problem. 2) Due to bird”s beak effects created by the prior art thermally formed BD/BS oxide layer 24, the lattice structure of the substrate 12 is damaged, and the reliability of the stacked-gate flash memory is hence dramatically reduced. 3) The formation of the BD/BS oxide layer 24 overly diffuses dopants into the drain and source resulting in a shortened channel length. This causes an occurrence of punch through between the source and the drain, influencing the electrical performance of the stacked-gate flash memory. And, finally, 4) An insufficient gate coupling ratio (GCR).

### SUMMARY OF INVENTION

It is therefore a primary objective of the present invention to provide a method of fabricating a high GCR stacked-gate non-volatile memory with a unique ISSG film for improving the reliability of the memory.

It is another objective of the present invention to precisely control the channel length of the stacked-gate flash memory and the thickness of the BD/BS oxide layer.

It is still another objective of the present invention to use an ISSG film to reduce random bit failures caused by acid penetration during the fabrication of the flash memory.

According to the preferred embodiment of the present invention, the method comprises the following steps: (1) Providing a substrate that has a channel region and a bit line region on its surface; (2) Forming a stacked layer on the substrate in the channel region. The stacked layer comprises a polysilicon layer and a sacrificial layer formed atop the polysilicon layer; (3) Oxidizing the stacked layer to create an ISSG film on the surface of the polysilicon layer and the surface of the sacrificial layer; (4) Depositing a dielectric layer over the ISSG film to cover the channel region and the bit line region. The top surface of the dielectric layer on the surface of the substrate is above the top surface of the polysilicon layer and below the top surface of the sacrificial layer; (5) Partially removing the dielectric layer and the ISSG layer to expose portions of the sacrificial layer; and (6) Completely removing the sacrificial layer.

It is an advantage that the present invention not only precisely controls the channel length of the stacked-gate flash memory and the thickness of the dielectric layer (used as a BD/BS oxide layer), but the present invention also effectively shrinks the size of the devices to improve the reliability of the devices. A 60 to 75% gate coupling ratio gain of the stacked-gate flash memory is achieved. Additionally, the ISSG film reinforces the interface between the dielectric layer and the polysilicon layer so as to prevent acid penetration and acid-corroded seams being formed during the acid solution dipping process. Random bit failures are thereby reduced.

These and other objectives of the present invention will no doubt become obvious to those of ordinary skill in the art after having read the following detailed description of the preferred embodiment that is illustrated in the various figures and drawings.

### BRIEF DESCRIPTION OF DRAWINGS

FIG. 1 to FIG. 4 are cross-sectional diagrams of forming a stacked-gate flash memory according to a prior art method; and

FIG. 5 to FIG. 11 are cross-sectional diagrams of forming a high-GCR flash memory according to the present invention

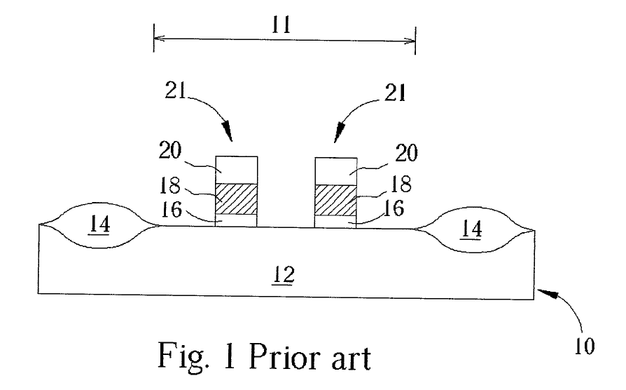

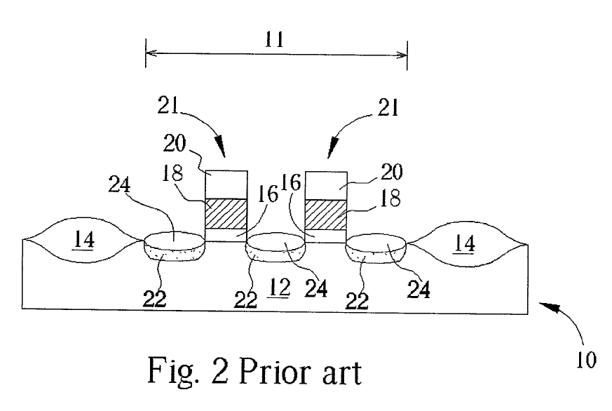

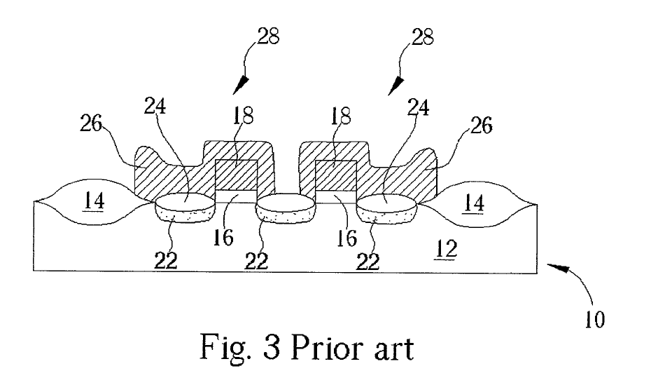

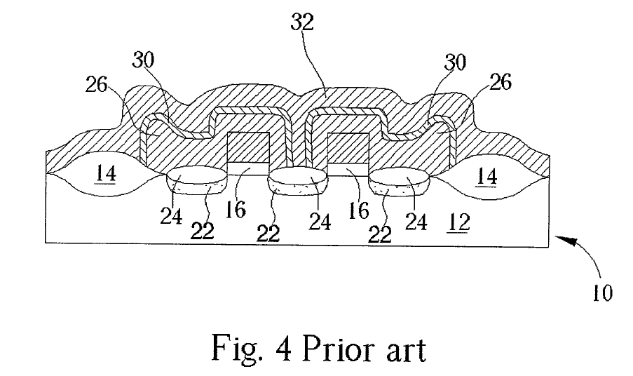

### DETAILED DESCRIPTION

A high-GCR flash memory with an ISSG film formed according to the preferred embodiment of the present invention will now be described in detail.

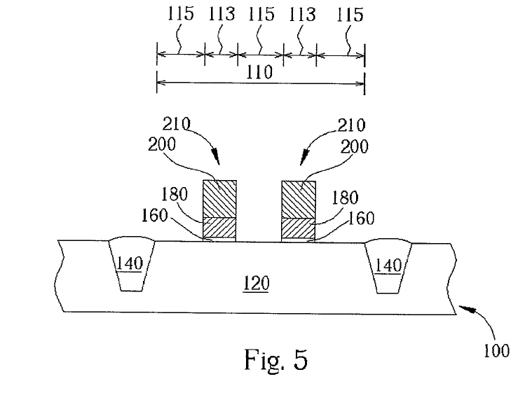

Please refer to FIG. 5 to FIG. 11. FIG. 5 to FIG. 11 are schematic diagrams showing a preferred embodiment of fabricating a high-GCR flash memory according to the present invention. As shown in FIG. 5, a semiconductor wafer 100 comprising a silicon substrate 120 is first provided. An active area 110, isolated by a shallow trench isolation region 140, is positioned in the silicon substrate 120. Two gate structures 210 are formed within the active area 110. Each gate structure 210 comprises a tunnel oxide layer 160 formed on the silicon substrate 120, a PL1 layer 180, which is composed of CVD-polysilicon, positioned on the gate oxide layer 160, and a silicon nitride sacrificial layer 200 positioned atop the PL1 layer 180. After the formation of the gate structures 210, the active area 110 is further divided into a channel region 113 and a bit line area 115.

In the preferred embodiment of the present invention, the silicon substrate 120 is a P-type single crystal silicon substrate with a <100> crystalline orientation. Alternatively, the semiconductor substrate may be a silicon-on-insulator (SOI) substrate, an epitaxy silicon substrate, or any other silicon substrate with various lattice structures. Preferably, the tunnel oxide layer 160 has a thickness of about 90 to 120 angstroms, more preferably 95 angstroms. The PL1 layer 180 has a thickness of about 1000 angstroms. The sacrificial layer 200 has a thickness of about 1800 to 1950 angstroms, preferably 1925 angstroms. The sacrificial layer 200 may be formed by a chemical vapor deposition (CVD) method, such as a low pressure CVD method, in a SiH₂Cl₂/NH₃ system, at a temperature of about 750° C. The PL1 layer 180 is deposited in a SiH₄ ambient at a temperature of about 620° C. Generally, the after-etch-inspect critical dimension (AEICD) of the PL1 layer 180, i.e. floating gate channel length, is about 0.34 micrometers.

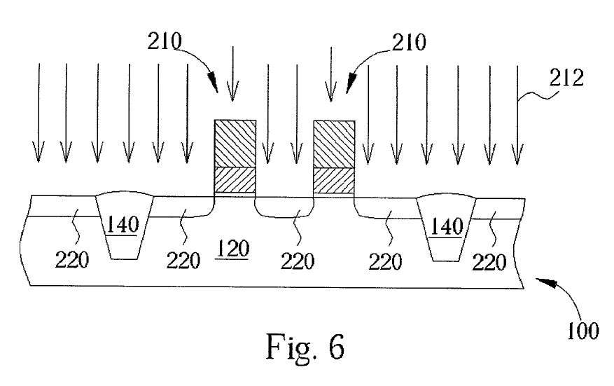

As shown in FIG. 6, an ion implantation process 212, using As (arsenic) as an ion source, is performed to implant As into the bit line region 115 of the silicon substrate 120 that is not covered by the gate structure 210 so as to form a doped region 220, which serves as a buried drain (BD) or a buried source (BS). In the preferred embodiment of the present invention, the ion implantation process 212 uses an As ion beam with an energy of about 50 KeV and a dosage of about 1E15 cm⁻². Optionally, a rapid thermal processing (RTP) is thereafter used to activate the doping region 220.

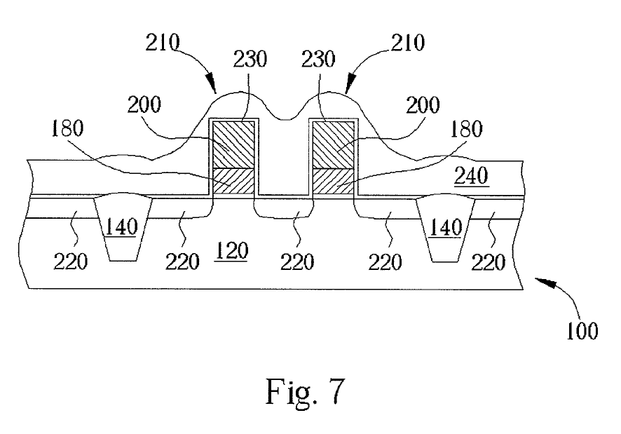

As shown in FIG. 7, an oxidation process in an atmosphere abundant with oxygen radicals and hydroxyl radicals is subsequently employed to form an ISSG (in-situ steam generation or in-situ steam growth) film 230 on the surface of the silicon nitride sacrificial layer 200, on the PL1 layer 180, and on the silicon substrate 120 surface. Preferably, the thickness of the ISSG film 230 is about 50 to 250 angstroms, more preferably between 100 to 150 angstroms. A high-density plasma CVD (HDPCVD) process is thereafter performed to deposit a 2000 to 3000 angstroms thick HDP oxide layer 240 over the ISSG film 230. The HDP oxide layer 240 covers the channel regions 113 and the bit line regions 115 of the active area 110. The top surface of the HDP oxide layer 240 within the bit line region 115 is above the top surface of the PL1 layer 180 and below the top surface of the sacrificial layer 200.

In the preferred embodiment of the present invention, the oxidation process with oxygen and hydroxyl radicals is an in-situ steam growth (ISSG) technique. The ISSG process is performed in a single wafer type RTP chamber, such as a RTP XEplus Centura type chamber available from Applied Materials, having 15 to 20 parallel-arrayed tungsten halogen lamps on its top to rapidly raise the temperature of the wafer to a required value. In the preferred embodiment of the present invention, the ISSG film 230 is formed in an H₂/O₂ system with a total gas flowrate (TGF) of about 10 SLM (standard liters per minute), with a preferred % H2 of TGF of 2% and a preferred RTP chamber pressure below 20 Torr, more preferably 10.5 Torr. At the beginning of the in-situ steam growth process, the silicon substrate 120 is lamp-heated to a temperature of about 1000° C. to 1200° C., more preferably 1150° C., and is maintained at this temperature for about 20 to 25 seconds. Under the unique <20 Torr low pressure system, the ISSG process is performed in a desired mass transport controlled regime, which is sensitive to pressure variations.

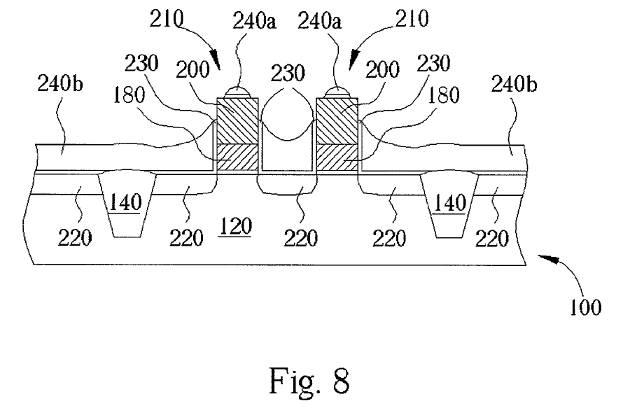

As shown in FIG. 8, a wet etching process using a DHF (diluted HF) solution or a BOE (buffered oxide etcher) solution as an etchant is performed to etch away a portion of the HDP oxide layer 240 and the ISSG film 230 to expose the sacrificial layer 200. In the preferred embodiment, the removed thickness of the HDP oxide layer 240 is about 650 to 900 angstroms, preferably about 700 angstroms. At this point, the original HDP oxide layer 240 is now divided into two discontinuous parts: a first HDP oxide layer 240a and a second HDP oxide layer 240b. The first HDP oxide layer 240a is on the sacrificial layer 200 and will be removed in the subsequent processes, while the second HDP oxide layer 240b is located adjacent to the gate structures 210. Notably, the ISSG film 230 reinforces the interface between the second HDP oxide layer 240b and the PL1 layer 180 so as to prevent acid penetration caused by the use of the DHF solution.

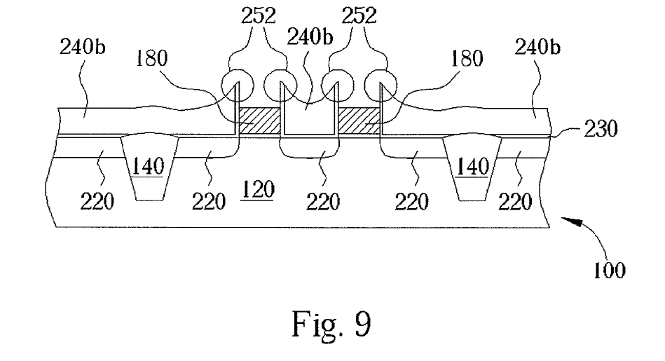

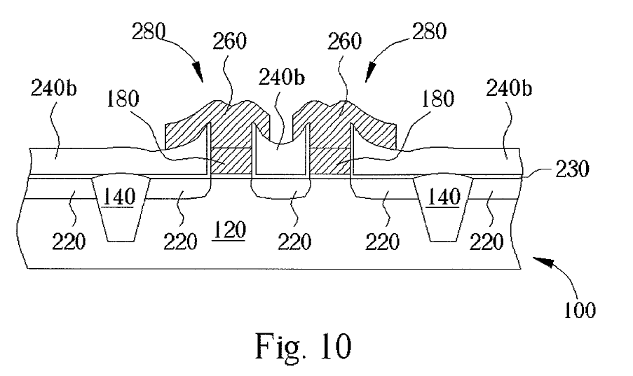

As shown in FIG. 9, the sacrificial layer 200 is then removed by using a method known in the art, such as a heated phosphoric acid solution. At the same time, the first HDP oxide layer 240a is also removed. A protrusion structure 252 of the second HDP oxide layer 240b is created near the PL1 layer after the removal of the sacrificial layer 200 and the first HDP oxide layer 240a. The protrusion structure 252 can improve the GCR with a gain of about 60% to 75%. An increased coupling ratio can be very beneficial in reducing the required operational voltage of a flash memory cell. As shown in FIG. 10, a floating gate 280 is completed by forming a polysilicon layer 260 over the PL1 layer 180. The polysilicon layer 260 is formed by a conventional CVD method, a lithographic process, and a dry etching process.

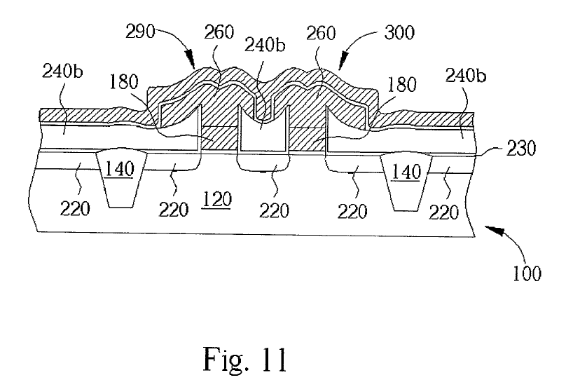

Finally, as shown in FIG. 11, a dielectric layer 290 is formed on the surface of the floating gate 280, and a polysilicon layer 300 is then formed that serves as a control gate of the stacked-gate flash memory cell. Typically, the dielectric layer 290 is an ONO structure that comprises a bottom oxide layer, a nitride layer positioned on the bottom oxide layer, and a top oxide layer positioned on the nitride layer. The ONO dielectric layer 290 is formed by ONO processes known in the art.

In comparison with the prior art method, the features of the present invention include: 1) The thermally formed BD/BS oxide layer is replaced with an HDP oxide layer 240b in the present invention, an additional thermal process thus being omitted. 2) The thickness of the HDP oxide layer 240b can be well controlled since it is formed by a CVD method. 3) A greatly improved GCR results from the special protrusion structure 252 of the HDP oxide layer 240b. 4) Resistance to HF-like acid solutions is provided by the unique ISSG film 230. 5) Random bit failures caused by acid penetration are reduced.

Those skilled in the art will readily observe that numerous modification and alterations of the advice may be made while retaining the teachings of the invention. Accordingly, the above disclosure should be construed as limited only by the metes and bounds of the appended claims.

What is claimed is:

1. A method for reducing random bit failures of a flash memory, the method comprising:
providing a substrate comprising a channel region and a bit line region on a surface of the substrate;
forming a stacked layer on the substrate in the channel region, wherein the stacked layer comprises a polysilicon layer and a sacrificial layer formed atop the polysilicon layer;
oxidizing the stacked layer to create an ISSG film on a surface of the polysilicon layer and a surface of the sacrificial layer;
depositing a dielectric layer over the ISSG film to cover the channel region and the bit line region, a top surface of the dielectric layer on the surface of the substrate being above a top surface of the polysilicon layer and below a top surface of the sacrificial layer;
partially removing the dielectric layer and the ISSG layer to expose portions of the sacrificial layer; and
completely removing the sacrificial layer;
wherein the ISSG film reinforces the interface between the dielectric layer and the polysilicon layer so as to prevent acid penetration and acid-corroded seams being formed during the acid solution dipping process, thereby reducing random bit failures.

2. The method of claim 1 wherein the ISSG film is formed by an in-situ steam growth (ISSG) method.

3. The method of claim 1 wherein the dielectric layer is a high density plasma (HDP) oxide layer.

4. The method of claim 1 wherein the substrate further comprises a doped area adjacent to the polysilicon layer in the bit line region, the doped area serving as a buried source (BS) or a buried drain (BD).

5. The method of claim 1 wherein the sacrificial layer is composed of silicon nitride.

6. The method of claim 1 wherein the dielectric layer and the ISSG film is wet-etched by means of a diluted HF (DHF) solution or a buffered oxide etcher (BOE) solution.

7. The method of claim 1 wherein the sacrificial layer is stripped by a 160° C. phosphoric acid solution.

8. The method of claim 1 wherein the acid solution dipping process uses a DHF solution.

9. The method of claim 1 wherein the substrate is a silicon substrate.

10. The method of claim 1 wherein the ISSG film has a thickness between 50 and 250 angstroms.
